(19) United States
(12) Patent Application Publication
(10) Pub. No.: US 2026/0100554 A1
(43) Pub. Date: Apr. 9, 2026

(54) LIGHT-EMITTING DEVICE

(71) Applicant: NICHIA CORPORATION, Anan-shi (JP)

(72) Inventors: Kenji OZEKI, Tokushima-shi (JP); Katsunori WAGI, Anan-shi (JP); Masahiro OKAZAKI, Anan-shi (JP); Terumitsu KASHIWAKI, Anan-shi (JP)

(21) Appl. No.: 19/348,549

(22) Filed: Oct. 2, 2025

(30) Foreign Application Priority Data
Oct. 4, 2024 (JP) 2024-175316

(51) Int. Cl. H01S 5/02315; H01S 5/00; H01S 5/028

(52) U.S. Cl. CPC H01S 5/02315; H01S 5/0078; H01S 5/0282

(57) ABSTRACT

A light-emitting device includes a substrate, a light-emitting element, a protective element, a light-transmissive member, and an adhesive member. The light-emitting element includes a support substrate and a semiconductor structure. The support substrate has a first lateral surface. The semiconductor structure is disposed on a lower surface of the support substrate. The light-emitting element is disposed such that a surface on a lower surface side of the light-emitting element faces an upper surface of the substrate. The protective element is disposed on the substrate such that the protective element faces the first lateral surface. The adhesive member bonds an upper surface of the support substrate and a lower surface of the light-transmissive member while covering the first lateral surface. An upper end of the first lateral surface is located at a greater distance from the protective element than a lower end of the first lateral surface is.

### CROSS-REFERENCE TO RELATED APPLICATION

This application claims priority to Japanese Patent Application No. 2024-175316, filed on Oct. 4, 2024, the disclosure of which is hereby incorporated herein by reference in its entirety.

### TECHNICAL FIELD

The present disclosure relates to a light-emitting device.

### BACKGROUND

A light-emitting device including a light-emitting element such as a light-emitting diode has been known. An example of such a light-emitting device includes a light-emitting element and a protective element on a substrate, and a light-transmissive member disposed on the light-emitting element via an adhesive resin (see, for example, Japanese Patent Publication No. 2024-49197).

In such a light-emitting device, the adhesive resin covers lateral surfaces of the light-emitting element, and thus the adhesive resin functions as a light guide member with respect to light emitted laterally from the light-emitting element. That is, the light emitted laterally from the light-emitting element is reflected by lateral surfaces of the adhesive resin to the light-transmissive member side, thereby improving light extraction efficiency of the light-emitting device.

### SUMMARY

The above-described light-emitting device may be desired to have further improved light extraction efficiency.

An object of the present disclosure is to provide a light-emitting device that can further improve light extraction efficiency.

A light-emitting device according to one embodiment of the present disclosure includes a substrate, a light-emitting element, a protective element, a light-transmissive member, and an adhesive member. The light-emitting element includes a support substrate and a semiconductor structure. The support substrate has an upper surface, a lower surface on an opposite side to the upper surface, and a first lateral surface between the upper surface and the lower surface. The semiconductor structure is disposed on the lower surface of the support substrate. The light-emitting element is disposed such that a surface on a lower surface side of the light-emitting element faces an upper surface of the substrate. The protective element is disposed on the substrate such that the protective element faces the first lateral surface. The light-transmissive member is disposed on an upper surface of the light-emitting element. The adhesive member bonds the upper surface of the support substrate and a lower surface of the light-transmissive member to each other while covering the first lateral surface. An upper end of the first lateral surface is located at a greater distance from the protective element than a lower end of the first lateral surface is.

According to one embodiment of the present disclosure, a light-emitting device that can further improve light extraction efficiency can be provided.

### BRIEF DESCRIPTION OF DRAWINGS

FIG. 1A is a schematic perspective view illustrating an example of a light-emitting device according to the present embodiment.

FIG. 1B is a schematic top view illustrating the light-emitting device in FIG. 1A.

FIG. 1C is a schematic side view illustrating the light-emitting device in FIG. 1A.

FIG. 1D is a schematic bottom view illustrating the light-emitting device in FIG. 1A.

FIG. 1E is a schematic cross-sectional view taken along line IE-IE of the light-emitting device in FIG. 1A.

FIG. 2 is a schematic partially enlarged cross-sectional view of a light-emitting element, a light-transmissive member, and an adhesive member in the light-emitting device in FIG. 1E.

FIG. 3A is another example of the light-emitting device according to the present embodiment and is a schematic top view illustrating a light-transmissive member and a light-emitting element.

FIG. 3B is a schematic side view of the light-transmissive member and the light-emitting element in FIG. 3A as viewed from an arrow R side.

FIG. 3C is a schematic side view of the light-transmissive member and the light-emitting element in FIG. 3A as viewed from an arrow U side.

FIG. 4A is a schematic perspective view illustrating another example of the light-emitting device according to the present embodiment.

FIG. 4B is a schematic cross-sectional view taken along line IVB-IVB of the light-emitting device in FIG. 4A.

FIG. 4C is a schematic cross-sectional view illustrating a modified example of the light-emitting device in FIG. 4B.

FIG. 5A is a schematic top view schematically illustrating another example of the light-emitting device according to the present embodiment.

FIG. 5B is a schematic top view illustrating a modified example of the light-emitting device in FIG. 5A.

FIG. 6A is a schematic top view illustrating still another example of the light-emitting device according to the present embodiment.

FIG. 6B is a schematic top view illustrating a modified example of the light-emitting device in FIG. 6A.

### DETAILED DESCRIPTION

Light-emitting devices according to embodiments of the present invention are described below with reference to the drawings. In the following description, terms indicating specific directions or positions (for example, “upper”, “above”, “upward”, “lower”, “below”, “downward” and other terms related to those terms) are used as necessary. The use of those terms, however, is to facilitate understanding of the invention with reference to the drawings, and the technical scope of the present invention is not limited by the meanings of those terms. Parts having the same reference characters appearing in a plurality of drawings indicate identical or equivalent parts or members.

The following embodiments exemplify light-emitting devices and the like for embodying the technical concept of the present invention, and the present invention is not limited to the description below.

The dimensions, materials, shapes, relative arrangements, and the like of components described below are not intended to limit the scope of the present invention to those alone but are intended to provide an example, unless otherwise specified. The contents described in one embodiment can be applied to other embodiments and modified examples. The size, positional relationship, and the like of the members illustrated in the drawings can be exaggerated to clarify the explanation. To avoid overcomplicating the drawings, end views illustrating only cut surfaces may be used as schematic views or cross-sectional views with some elements being omitted. The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

### First Embodiment

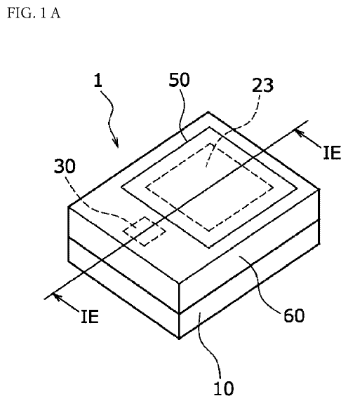

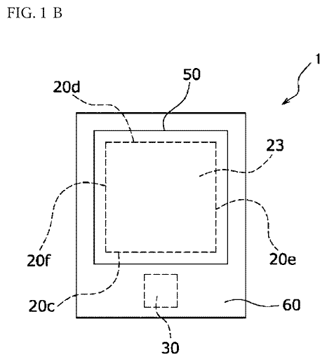

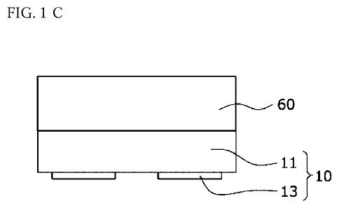

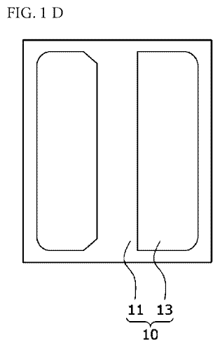

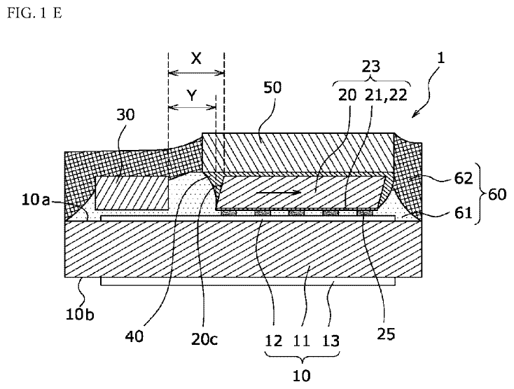

As illustrated in FIGS. 1A to 1E, a light-emitting device 1 according to the present embodiment includes a substrate 10, a light-emitting element 23, a protective element 30, an adhesive member 40, and a light-transmissive member 50. The light-emitting element 23 includes a support substrate 20 having an upper surface 20a, a lower surface 20b on an opposite side to the upper surface 20a, and a first lateral surface 20c between the upper surface 20a and the lower surface 20b, and a semiconductor structure 21 disposed on the lower surface 20b of the support substrate 20. The light-emitting element 23 is disposed such that a surface of the support substrate 20 on the lower surface 20b side faces an upper surface of the substrate 10. The light-transmissive member 50 is disposed on an upper surface of the light-emitting element 23 (that is, the upper surface of the support substrate 20) via the adhesive member 40. The light-emitting device 1 may be further provided with a covering member 60 from which the upper surface of the light-transmissive member 50 is exposed while covering the protective element 30.

In the light-emitting device 1, the protective element 30 is disposed on the substrate 10 so as to face the first lateral surface 20c of the support substrate 20. The light-emitting element 23 is disposed on the substrate 10 such that the upper end of the first lateral surface 20c of the support substrate 20 is located at a greater distance from the protective element 30 than the lower end of the first lateral surface 20c is. The adhesive member 40 bonds the upper surface 20a of the support substrate 20 and a lower surface 50b of the light-transmissive member 50 to each other. Further, the adhesive member 40 preferably covers at least the first lateral surface 20c of the support substrate 20.

In the present specification, the expression “the upper end of the first lateral surface 20c of the support substrate 20 is located at a greater distance from the protective element 30 than the lower end of the first lateral surface 20c is” means that, for example, as illustrated in FIG. 1E, in a direction parallel to the upper surface of the substrate 10 and in a direction in which the light-emitting element 23 and the protective element 30 are arrayed, a distance X from the protective element 30 to the upper end of the first lateral surface 20c of the support substrate 20 in the light-emitting element 23 is longer than a distance Y from the protective element 30 to the lower end of the first lateral surface 20c. In FIG. 1E, an inclination direction in which the first lateral surface 20c is inclined from the lower end to the upper end thereof is indicated by an arrow. The upper end of the first lateral surface 20c means a portion located at the uppermost position (specifically, a position farthest from the upper surface of the substrate 10) in the outer edge of the first lateral surface 20c, and the lower end means a portion located at the lowermost position (specifically, a position closest to the upper surface of the substrate 10) in the outer edge of the first lateral surface 20c. For example, the upper end of the first lateral surface 20c of the support substrate 20 illustrated in FIG. 1E is a portion in contact with the upper surface 20a (that is, a boundary portion with the upper surface 20a), and the lower end is a portion in contact with the lower surface 20b (that is, a boundary portion with the lower surface 20b).

With such a configuration, absorption of the light having exited from the first lateral surface 20c of the support substrate 20 by the protective element 30 can be reduced, and the light extraction efficiency of the light-emitting device 1 can be improved.

Furthermore, when the adhesive member 40 covers the first lateral surface 20c of the support substrate 20, the light having exited from the first lateral surface of the support substrate is facilitated to be guided to the light-transmissive member 50. In the present embodiment, the upper end of the first lateral surface 20c is located at a greater distance from the protective element 30 than the lower end of the first lateral surface 20c is, and thus the adhesive member 40 and the protective element 30 can be facilitated to be separated from each other. This allows the amount of the adhesive member 40 covering the first lateral surface 20c of the support substrate 20 to increase, thereby increasing the area of the first lateral surface 20c of the support substrate 20 covered with the adhesive member 40. Thus, the light extraction efficiency of the light-emitting device 1 can be further improved.

Further, in a manufacturing process of the light-emitting device 1, the adhesive member 40 covering the first lateral surface 20c of the support substrate 20 can be less likely to contact with the protective element 30.

### Substrate 10

As illustrated in FIG. 1E, the substrate 10 is a member on which the light-emitting element 23 is disposed. The substrate 10 may have, for example, a substantially rectangular parallelepiped shape or a substantially cubic shape. The substrate 10 may have, on the upper surface thereof, a recessed portion where the light-emitting element is to be disposed. The substrate 10 includes a wiring for supplying electric power to the light-emitting element from the outside, and a base body 11 for supporting the wiring.

The base body 11 preferably has insulation properties. The base body 11 is preferably formed of a material that is less likely to transmit light emitted from the light-emitting element 23, external light, and the like. Examples of the material of the base body 11 include a single material selected from ceramics such as aluminum oxide, aluminum nitride, silicon nitride, and mullite, resins such as epoxy resin, silicone resin, modified epoxy resin, urethane resin, phenol resin, polyimide resin, BT resin, and polyphthalamide, semiconductors such as silicon, and metals such as copper and aluminum, and composite materials thereof. Among these, a ceramic having good heat dissipation properties can be suitably used as the material of the base body 11.

The substrate 10 includes, as a wiring, an upper surface wiring 12 disposed on an upper surface 10a on which at least the light-emitting element 23 is disposed. Further, the substrate 10 may include, as the wiring, a lower surface wiring 13 disposed on a lower surface 10b on an opposite side to the upper surface 10a of the substrate 10.

The upper surface wiring 12 includes a wiring electrically connected to the light-emitting element 23 and a wiring electrically connected to the protective element 30. The lower surface wiring 13 includes an anode electrode and a cathode electrode each electrically connected to an external power supply. For the upper surface wiring 12 and the lower surface wiring 13, for example, a metal such as iron, copper, nickel, aluminum, gold, silver, platinum, titanium, tungsten, or palladium, or an alloy containing at least one of these metals can be used. The substrate 10 may include a relay wiring for connecting the upper surface wiring 12 and the lower surface wiring 13 inside and/or on the lateral surface of the base body 11. The substrate 10 may include, on the lower surface, a heat dissipation wiring electrically independent of the lower surface wiring.

In a case in which the substrate 10 does not include the lower surface wiring 13, an anode electrode and a cathode electrode electrically connected to an external power supply may be disposed on the upper surface or the lateral surface of the substrate 10.

The light-emitting device 1 may have a structure that does not include the substrate 10. For example, the light-emitting device 1 may have a structure in which element electrode(s) 22 of the light-emitting element 23 and/or a conductive member such as a plating layer disposed on the element electrode(s) 22 of the light-emitting element 23 is provided as an external connection electrode of the light-emitting device 1. The element electrode(s) 22 and/or the conductive member are exposed from the covering member 60 covering the lower surface of the light-emitting element 23.

In the case in which two or more light-emitting elements 23 are disposed on the substrate 10, the wiring provided in the substrate 10 may be configured to collectively drive the light-emitting elements 23 or may be configured to individually drive the light-emitting elements 23.

### Light-Emitting Element 23

A semiconductor light-emitting element, such as a light-emitting diode (LED) chip or a semiconductor laser (LD) chip, can be suitably used for the light-emitting element 23. The shape, the size, and the like of the light-emitting element 23 can be optionally selected.

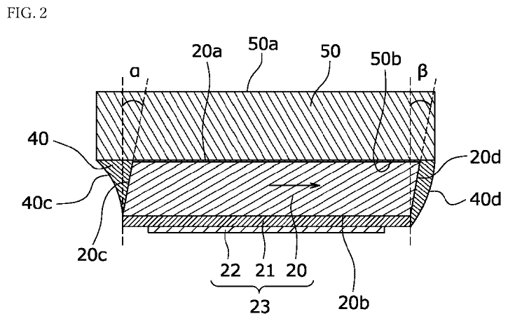

As illustrated in FIGS. 1B, 1E, and 2, the light-emitting element 23 includes the support substrate 20, the semiconductor structure 21, and the element electrode(s) 22. The support substrate 20 has the upper surface 20a, the lower surface 20b on an opposite side to the upper surface 20a, and the first lateral surface 20c that is the lateral surface located between the upper surface 20a and the lower surface 20b and faces the protective element in the light-emitting device 1. The semiconductor structure 21 is disposed on the lower surface 20b of the support substrate 20. The element electrode(s) 22 is disposed on the surface of the semiconductor structure 21 on an opposite side to the support substrate 20. The thickness of the light-emitting element 23 is, for example, in a range from 100 μm to 300 μm. The total thickness of the semiconductor structure 21 and the element electrode 22 in the thickness of the light-emitting element 23 is in a range from about 5 μm to about 20 μm. That is, the support substrate 20 has a thickness of at least ⅘ of the thickness of the light-emitting element 23.

The upper surface 20a and the lower surface 20b of the support substrate 20 each have, for example, a quadrilateral shape such as a square shape or a rectangular shape. In this case, the support substrate 20 has a second lateral surface 20d located between the upper surface 20a and the lower surface 20b and located on an opposite side to the first lateral surface 20c. Further, the support substrate 20 has a third lateral surface 20e and a fourth lateral surface 20f each adjacent to the first lateral surface 20c and the second lateral surface 20d. The upper surface 20a and the lower surface 20b of the support substrate 20 each may have a polygonal shape such as a triangular shape, a quadrangular shape, or a hexagonal shape.

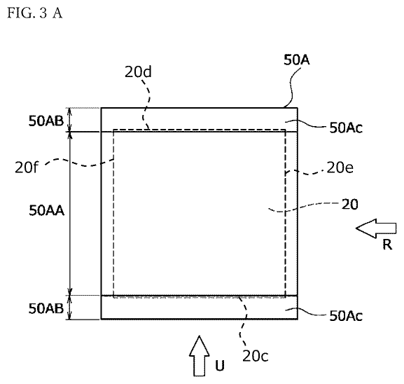

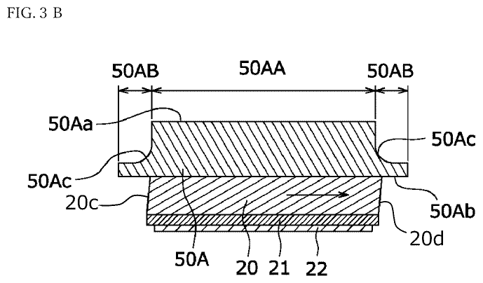

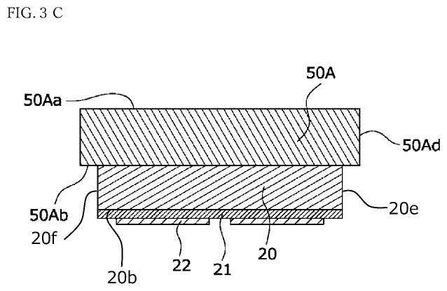

All of the first lateral surface 20c, the second lateral surface 20d, the third lateral surface 20e, and the fourth lateral surface 20f of the support substrate 20 may be perpendicular to the lower surface 20b of the support substrate 20 (see, for example, FIG. 3C), or one or more thereof may be inclined with respect to the lower surface 20b. That is, the external shape of the support substrate 20 may be a substantially rectangular parallelepiped shape or a substantially cubic shape, a polygonal columnar or frustum shape, a polyhedron (for example, hexahedron) in which one or more of the first lateral surface 20c, the second lateral surface 20d, the third lateral surface 20e, and the fourth lateral surface 20f are inclined with respect to the lower surface 20b of the light-emitting element, or the like. Among these, the external shape of the support substrate 20 is preferably a hexahedron in which the upper surface and the lower surface are substantially quadrilateral and the first lateral surface 20c and the second lateral surface 20d are inclined with respect to the lower surface 20b. Further, the hexahedron is more preferable in which the upper surface and the lower surface are substantially quadrilateral, and the first lateral surface 20c and the second lateral surface 20d are inclined in the same direction with respect to the lower surface 20b, that is, the first lateral surface 20c and the second lateral surface 20d are substantially parallel to each other. The third lateral surface 20e and the fourth lateral surface 20f are preferably substantially perpendicular to the lower surface 20b of the support substrate 20.

Here, the inclination with respect to the lower surface 20b is, for example, 90°±4° or more and 10° or less. Further, the terms “substantially parallel” and “substantially perpendicular” mean that an inclination of ± less than 3° with respect to parallel and an inclination of ± less than 3° with respect to perpendicular, respectively, are allowed.

The light-emitting element 23 is disposed on the substrate 10 such that the surface of the support substrate 20 on the lower surface 20b side faces the upper surface 10a of the substrate 10. The upper surface 20a of the support substrate 20 functions as a main light-extracting surface of the light-emitting element 23. In FIGS. 1A to 1E, a form in which one light-emitting element 23 is disposed on the substrate 10 is illustrated, and the number of the light-emitting elements 23 disposed on the substrate 10 may be two or more, for example, two, three, and four or more. The support substrate 20 of the light-emitting element 23 has the first lateral surface 20c facing the protective element 30 described later. In the light-emitting device 1, as described above, the light-emitting element 23 is configured such that the upper end of the first lateral surface 20c of the support substrate 20 is located at a greater distance from the protective element 30 than the lower end of the first lateral surface 20c of the support substrate 20 is. To achieve such an arrangement of the light-emitting element 23 and the protective element 30, the following examples (i) to (iv) are given.
(i) The lateral surface of the protective element 30, which will be described later, facing the light-emitting element 23 is inclined in a direction away from the upper end of the first lateral surface 20c.
(ii) The protective element 30, which will be described later, is disposed on the substrate 10 in an inclined manner such that a lateral surface of the protective element 30 facing the light-emitting element 23 is inclined in a direction away from the upper end of the first lateral surface 20c.
(iii) The light-emitting element 23 is disposed on the substrate 10 in an inclined manner such that the upper end of the first lateral surface 20c is located at a greater distance from the protective element 30 than the lower end of the first lateral surface 20c is, regardless of whether the first lateral surface 20c of the support substrate 20 in the light-emitting element 23 is perpendicular to the lower surface 20b.
(iv) As illustrated in FIGS. 1E and 2, the first lateral surface 20c of the support substrate 20 in the light-emitting element 23 is inclined with respect to the lower surface 20b, and the light-emitting element 23 is disposed on the substrate 10 such that the upper end of the first lateral surface 20c of the support substrate 20 is located at a greater distance from the protective element 30 than the lower end of the first lateral surface 20c of the support substrate 20 is. In this case, the upper end of the second lateral surface 20d is preferably farther away from the protective element 30 than the lower end of the second lateral surface 20d is. That is, the first lateral surface 20c and the second lateral surface 20d are preferably inclined with respect to the lower surface 20b of the support substrate 20.

Among these, the example of (iv) is preferable, and for example, as illustrated in FIG. 2, it is more preferable that the first lateral surface 20c is inclined at (90°−α°) with respect to the lower surface 20b of the support substrate 20, and the second lateral surface 20d is inclined at (90°−β°) with respect to the lower surface 20b of the support substrate 20. Further, the upper surface of the light-emitting element 23 (that is, the upper surface of the support substrate 20) and the upper surface of the protective element 30 are preferably substantially parallel to the upper surface 10a of the substrate 10. Specifically, as illustrated in FIG. 1E, the support substrate 20 preferably has a parallelogram shape in which the bottom side is parallel to the upper surface of the substrate 10 in the cross-sectional shape of the light-emitting element 23. In this case, an angle formed by the lower surface 20b and the first lateral surface 20c is an acute angle.

When the support substrate 20 of the light-emitting element 23 has such a shape, mounting of the light-emitting element 23 on the substrate 10 can be facilitated. Furthermore, because the optical axis of the light emitted from the light-emitting device 1 is perpendicular to the upper surface of the substrate, for example, when the light-emitting device 1 is used in combination with a lens or the like, the optical design of the lens is facilitated. Here, α° and β° in FIG. 2 are, for example, in a range from 4° to 10°. Although α may be different from β, it is preferred that α=β.

The semiconductor structure 21 includes an n-side semiconductor layer, a p-side semiconductor layer, and a light-emitting layer interposed between the n-side semiconductor layer and the p-side semiconductor layer. The light-emitting layer may have a single quantum well (SQW) structure, or may have a multi quantum well (MQW) structure including a plurality of well layers. The semiconductor structure includes a plurality of semiconductor layers formed of nitride semiconductors. Examples of the nitride semiconductor include semiconductors having all compositions in which in a chemical formula of InₓAl_{y}Ga₁₋ₓ₋N (0≤x, 0≤y, and x+y≤1), composition ratios x and y are changed within respective ranges. The light emission peak wavelength of the light-emitting layer can be selected as appropriate according to the purpose. The active layer is configured to emit visible light or ultraviolet light, for example.

Examples of the support substrate include an insulating substrate of sapphire, spinel (MgAl₂O₄), or the like, and a nitride-based semiconductor substrate of gallium nitride or the like. For the support substrate, a material having transmissivity such as sapphire is preferably used. When a semiconductor structure is formed using a sapphire wafer as the support substrate and divided into individual light-emitting elements, each pair of lateral surfaces may be inclined with respect to the normal line of the upper surface due to cleavage or splitting. Accordingly, the above-described form (iv) can be obtained by cleaving or splitting thereof using the sapphire wafer. Furthermore, in a case in which dicing or the like is performed, the above-described forms (i) to (iii) and (iv) can be easily obtained even when any material of the support substrate is used.

The light-emitting element 23 may include one semiconductor structure 21 on support substrate 20, or may include a plurality of the semiconductor structures 21 on one support substrate 20. Furthermore, one semiconductor structure 21 may include only one light-emitting layer, or may include a plurality of light-emitting layers. The structure of the semiconductor structure 21 including the plurality of light-emitting layers may be a structure including the plurality of light-emitting layers between one n-side semiconductor layer and one p-side semiconductor layer, or may be a structure including the n-side semiconductor layer, the light-emitting layer, and the p-side semiconductor layer in sequence, repeated multiple times.

In the light-emitting element 23, the element electrode(s) 22 is disposed on the semiconductor structure 21. The element electrodes 22 include an n-electrode connected to the n-side semiconductor layer and a p-electrode connected to the p-side semiconductor layer. The p-electrode and the n-electrode may be disposed on different surfaces of the semiconductor structure 21, or may be disposed on the same surface. Here, the element electrodes 22 including the p-electrode and the n-electrode are disposed on the same surface of the semiconductor structure 21, and the side on which the element electrodes 22 are disposed constitutes the lower surface of the light-emitting element 23. In this case, the light-emitting element 23 can be flip-chip mounted on the substrate 10 with the lower surface (that is, the surface on the side provided with the element electrode 22) facing the substrate 10 side. The element electrodes 22 of the light-emitting element 23 are electrically connected to the upper surface wiring 12 via a conductive bonding member 25. As the conductive bonding member 25, for example, a known member such as eutectic solder, conductive paste, or bump can be used.

The light-emitting element 23 may include an optical film on the upper surface 20a of the support substrate 20. Examples of the optical film include a multilayer structure in which a low refractive index layer and a high refractive index layer are optionally layered on an underlying layer formed of an oxide film or the like. Such an optical film obtained by alternately layering films having different refractive indices at a ¼ wavelength thickness, for example, can transmit and/or reflect a predetermined wavelength with high efficiency. As a material, at least one type of oxide and/or nitride selected from the group consisting of, for example, Si, Ti, Zr, Nb, Ta, and Al can be contained. Specific examples thereof include a single-layer film of SiO₂, a multilayer film of SiON/SiO₂, and a multilayer film of Nb₂O₅/SiO₂.

### Protective Element 30

In the light-emitting device 1, the protective element 30 is disposed on the substrate 10 so as to face the light-emitting element 23 (specifically, so as to face the first lateral surface 20c of the support substrate 20 of the light-emitting element 23).

The protective element 30 protects the light-emitting element 23 from a surge current or static electricity, and examples thereof include a Zener diode.

The lateral surface of the protective element 30 facing the light-emitting element 23 may be perpendicular or inclined with respect to the lower surface of the protective element 30. Further, the lateral surface of the protective element 30 facing the light-emitting element 23 may be inclined at an angle of 90°±4° or more and 10° or less with respect to the upper surface 10a of the substrate 10, or may be substantially perpendicular to the upper surface 10a of the substrate 10. In other words, the protective element 30 may be disposed on the substrate 10 in an inclined manner or substantially perpendicular manner, regardless of whether the lateral surface facing the light-emitting element 23 is inclined with respect to the lower surface of the protective element 30. Here, the terms “substantially perpendicular” mean that the inclination less than ±3° with respect to perpendicular is allowed.

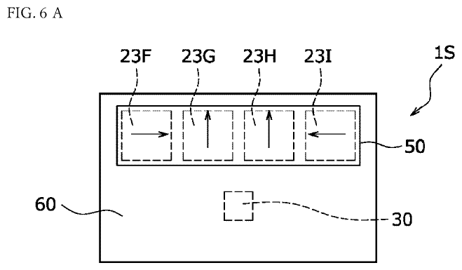

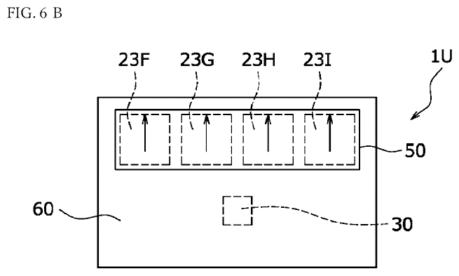

At least one protective element 30 is disposed in the light-emitting device 1. In the case in which the light-emitting device 1 includes a plurality of the light-emitting elements 23, one protective element 30 may be disposed, or a plurality of the protective elements 30 may be disposed. The expression “disposed so as to face the first lateral surface 20c of the support substrate 20 in the light-emitting element 23” means that the entirety or part of the lateral surface of the protective element 30 facing the light-emitting element 23 overlaps the first lateral surface 20c of the support substrate 20 as viewed from one direction as illustrated in FIGS. 1B, 6A, and the like.

The protective element 30 is disposed on the substrate 10 such that the lateral surface of the protective element 30 faces the lateral surface of the support substrate 20 of the light-emitting element 23. A distance between the light-emitting element 23 and the protective element 30 on the substrate 10 is preferably short in terms of size reduction in the light-emitting device 1, but is preferably long in terms of reducing light absorption by the protective element 30. Specifically, the light-emitting element 23 and the protective element 30 in a plane parallel to the upper surface of the substrate 10 are preferably away from each other at a shortest distance in a range from 100 μm to 300 μm, more preferably in a range from 150 μm to 250 μm.

### Adhesive Member 40

The adhesive member 40 is disposed between the upper surface of the light-emitting element 23 (specifically, the upper surface 20a of the support substrate 20) and the lower surface 50b of the light-transmissive member 50, and bonds the light-emitting element 23 and the light-transmissive member 50 to each other. The adhesive member 40 preferably covers the first lateral surface 20c of the support substrate 20. Furthermore, it is preferable that the adhesive member 40 continuously covers, in addition to the first lateral surface 20c, a plurality of lateral surfaces, that is, the second lateral surface 20d, the third lateral surface 20e, and the fourth lateral surface 20f each being continuous with the upper surface 20a. Specifically, the adhesive member 40 preferably continuously covers the entire upper surface 20a of the support substrate 20 and at least part of each of the upper end sides of the first lateral surface 20c, the second lateral surface 20d, the third lateral surface 20e, and the fourth lateral surface 20f. That is, the adhesive member 40 preferably covers a larger area of each lateral surface of the support substrate 20. Specifically, in each lateral surface of the support substrate 20, 75% or more and 100% or less of a region from the upper end side in the height direction is preferably covered with the adhesive member 40, and 90% or more and 100% or less of the region from the upper end side in the height direction is more preferably covered with the adhesive member 40. The adhesive member 40 covers the lower surface 50b of the light-transmissive member 50. By such an arrangement of the adhesive member 40, the light emitted from the lateral surface of the light-emitting element 23 is facilitated to be guided to the light-transmissive member 50, so that the light extraction efficiency of the light-emitting device 1 can be improved. In particular, the adhesive member 40 preferably covers the entirety of the lower surface 50b of the light-transmissive member 50. This allows a larger amount of the light emitted from the light-emitting element 23 to enter the lower surface 50b of the light-transmissive member 50 through the adhesive member 40.

As illustrated in FIG. 2, the adhesive member 40 has a lateral surface 40c facing the first lateral surface 20c and a lateral surface 40d facing the second lateral surface 20d.

For example, as in the example (iv) described above, in the case in which the first lateral surface 20c and the second lateral surface 20d of the support substrate 20 are inclined with respect to the lower surface 20b, and the upper surface of the support substrate 20 is substantially parallel to the upper surface 10a of the substrate 10, an angle formed by the first lateral surface 20c of the support substrate 20 and the lower surface 50b of the light-transmissive member 50 is different from an angle formed by the second lateral surface 20d of the support substrate 20 and the lower surface 50b of the light-transmissive member 50. Specifically, the angle formed by the first lateral surface 20c of the support substrate 20 and the lower surface 50b of the light-transmissive member 50 is an acute angle, and the angle formed by the second lateral surface 20d of the support substrate 20 and the lower surface 50b of the light-transmissive member 50 is an obtuse angle. Thus, when the amount of the adhesive member 40 disposed between the first lateral surface 20c of the support substrate 20 and the lower surface 50b of the light-transmissive member 50 is substantially the same as the amount of the adhesive member 40 disposed between the second lateral surface 20d of the support substrate 20 and the lower surface 50b of the light-transmissive member 50, the lateral surface 40c and the lateral surface 40d of the adhesive member 40 have shapes different from each other in a cross-sectional view.

During the manufacturing of the light-emitting device 1, the light-transmissive member 50 is disposed on the light-emitting element 23 via the adhesive member 40. In this case, the uncured adhesive member 40 covering the lateral surface of the light-emitting element 23 and the lower surface of the light-transmissive member 50 tends to keep a smaller surface area due to surface tension, and thus surface shapes of the lateral surface 40c and the lateral surface 40d of the adhesive member 40 tend to be a concave curved surface or a convex curved surface. Thus, in the manufacturing process of the light-emitting device 1, by adjusting the viscosity and the amount of the uncured adhesive member, the lateral surface 40c and the lateral surface 40d of the adhesive member 40 can each be disposed with a desired shape. For example, the outer surfaces of the lateral surface 40c and the lateral surface 40d of the adhesive member 40 can each have an outer surface including a concave curved surface, and the curvature radius of the curved surface of the lateral surface 40c can be smaller than the curvature radius of the curved surface of the lateral surface 40d. The outer surfaces of the lateral surface 40c and the lateral surface 40d of the adhesive member 40 can each have an outer surface including a convex curved surface, and the curvature radius of the curved surface of the lateral surface 40c can be larger than the curvature radius of the curved surface of the lateral surface 40d. The lateral surface 40c of the adhesive member 40 can have an outer surface including a concave curved surface, and the lateral surface 40d can have an outer surface including a concave curved surface. In particular, the lateral surface 40d of the adhesive member 40 covering the second lateral surface 20d of the support substrate 20 preferably has an outer surface including a convex curved surface as illustrated in FIG. 2. This allows light emitted laterally from the lower end side of the second lateral surface 20d of the support substrate 20 to be easily reflected at the lateral surface 40d of the adhesive member 40 to be directed upward of the light-emitting element 23. Thus, the light incident on the light-transmissive member 50 is increased, and the light extraction efficiency in the light-emitting device 1 can be improved.

The lateral surface 40c of the adhesive member 40 covering the first lateral surface 20c preferably has an outer surface including a concave curved surface. This can increase a distance with which the lateral surface 40c of the adhesive member 40 and the protective element 30 are apart from each other, thereby reducing the light absorbed by the protective element 30. Thus, the light incident on the light-transmissive member 50 is increased, and the light extraction efficiency in the light-emitting device 1 can be improved.

The lower end of the lateral surface 40d of the adhesive member 40 covering the second lateral surface 20d is preferably closer to the substrate 10 than the lower end of the lateral surface 40c of the adhesive member 40 covering the first lateral surface 20c is. The second lateral surface 20d is inclined such that an outer surface thereof becomes closer to the upper surface of the substrate. In other words, a distance from the second lateral surface 20d to the outer lateral surface of the light-emitting device 1 decreases from the lower end toward the upper end. Thus, when the adhesive member 40 covers a larger region on the lower end side of the second lateral surface 20d, the light emitted laterally from the second lateral surface 20d can be reflected to the light-transmissive member 50 side in combination with a convex shape of the lateral surface 40d of the adhesive member 40. This can reduce unintended light leakage from the lateral direction in the light-emitting device 1.

The outer surfaces of the adhesive member 40 covering the third lateral surface 20e and the fourth lateral surface 20f of the support substrate 20 may each include a concave curved surface or a convex curved surface. Portions of the adhesive member 40 covering the third lateral surface 20e and the fourth lateral surface 20f preferably have the same shape. In a top view, the area of the lower surface 50b of the light-transmissive member 50 located outward of the third lateral surface 20e is equal to the area of the lower surface 50b of the light-transmissive member 50 located outward of the fourth lateral surface 20f, and when the angle formed by the third lateral surface and the lower surface 50b of the light-transmissive member 50 is equal to the angle formed by the fourth lateral surface and the lower surface 50b of the light-transmissive member 50, portions of the adhesive member 40 covering the third lateral surface 20e and the fourth lateral surface 20f can have the shape equivalent to each other.

The adhesive member 40 is preferably located apart from the protective element 30 and the substrate 10. This allows the adhesive member 40 to have a desired lateral surface shape. Furthermore, the likelihood of absorption of the light emitted from the light-emitting element 23 by the protective element 30 and/or the substrate 10 through the adhesive member 40 can be reduced.

The adhesive member 40 is a member for bonding the light-transmissive member 50 and the light-emitting element 23 to each other. The adhesive member 40 can be formed when an uncured adhesive resin for bonding the light-transmissive member 50 and the light-emitting element 23 to each other is spread to the lateral surface of the light-emitting element 23 and then is cured. Further, the adhesive member 40 is a member for guiding the light emitted from the light-emitting element 23 to the light-transmissive member 50, and has transmissivity to the light emitted from the light-emitting element 23. Examples of the adhesive resin to be the adhesive member 40 after being cured include thermosetting resins such as an epoxy resin, a modified epoxy resin, a silicone resin, and a modified silicone resin. Among them, a silicone resin having high heat resistance is preferably used. The adhesive member 40 may contain a light diffusion member and/or a phosphor to be described later.

### Light-Transmissive Member 50

The light-transmissive member 50 is disposed on the upper surface of the light-emitting element 23 via the adhesive member 40. The light-transmissive member 50 is a member that transmits the light emitted from the light-emitting element 23 and lets the light exit to the outside. The light-transmissive member 50 is disposed such that the lower surface 50b of the light-transmissive member 50 is substantially parallel to the upper surface of the light-emitting element 23 (that is, the upper surface 20a of the support substrate 20). The light-transmissive member 50 transmits 60% or more, preferably 70% or more, of light from the light-emitting element 23 and/or wavelength-converted light of the light from the light-emitting element 23 (e.g., light having wavelengths in the range of 320 nm to 850 nm).

As illustrated in FIG. 2, the light-transmissive member 50 has an upper surface 50a, a lower surface 50b on an opposite side to the upper surface 50a, and lateral surfaces between the upper surface 50a and the lower surface 50b. The upper surface 50a of the light-transmissive member 50 serves as the main light-emitting surface of the light-emitting device 1 and constitutes the upper surface of the light-emitting device 1.

The upper surface 50a and the lower surface 50b of the light-transmissive member 50 each preferably have a quadrilateral shape such as a square shape or a rectangular shape. The upper surface 50a and the lower surface 50b are preferably parallel to each other. As illustrated in FIG. 2 and the like, all of the lateral surfaces of the light-transmissive member 50 may be perpendicular to the upper surface 50a or the lower surface 50b, one or more the lateral surfaces may be inclined from the upper surface 50a toward the lower surface 50b, or as illustrated in FIGS. 3A to 3C, one or more of the lateral surfaces may have an outer surface including a curved surface that is concave from an upper surface 50Aa toward a lower surface 50Ab. In addition, one or more of the lateral surfaces may have a shape having a step between the upper surface 50a and the lower surface 50b. For example, as illustrated in FIGS. 3A to 3C, a light-transmissive member 50A may include a first portion 50AA and second portions 50AB. The first portion 50AA is a portion in which the upper surface 50Aa and the lower surface 50Ab of the light-transmissive member 50A overlap each other. The second portions 50AB are located on outward of the first portion 50AA in a top view. The second portion 50AB may have a curved surface 50Ac. A surface 50Ad perpendicular to the upper surface 50Aa and the lower surface 50Ab may be provided therebetween. In this case, the second portion 50AB of the light-transmissive member 50A preferably overlaps part or the entirety of the first lateral surface 20c of the support substrate 20 in the light-emitting element 23 in a top view. Note that the upper surface 50a and the lower surface 50b of the light-transmissive member 50 may have a polygonal shape such as a triangular shape, a quadrangular shape, or a hexagonal shape.

The shape of the lower surface 50b of the light-transmissive member 50 is preferably similar to the shape of the upper surface of the light-emitting element 23 (that is, the upper surface 20a of the support substrate 20). For example, when the upper surface 20a of the support substrate 20 has a quadrilateral shape, the lower surface 50b of the light-transmissive member 50 also preferably has a quadrilateral shape.

The lower surface 50b of the light-transmissive member 50 is preferably a flat surface parallel to the upper surface of the light-emitting element 23. The upper surface 50a of the light-transmissive member 50 may be a flat surface parallel to the lower surface 50b, or part of the entirety of the upper surface 50a may include a surface that is not parallel to the lower surface 50b. The light-transmissive member 50 may have a minute uneven structure on part or the entirety of the surface of the light-transmissive member 50.

The lower surface 50b of the light-transmissive member 50 preferably has an area larger than an area of the upper surface of the light-emitting element 23. The light-transmissive member 50 is preferably disposed such that the lower surface 50b of the light-transmissive member 50 encloses the light-emitting element 23 in a top view. Specifically, in the light-emitting device 1, the lower surface 50b of the light-transmissive member 50 preferably encloses the upper surface 20a and the lower surface 20b of the support substrate 20 in a top view. The upper surface 50a of the light-transmissive member 50 may have an area larger than the lower surface 50b, may have the same area as the lower surface 50b, or may have an area smaller than the lower surface 50b. For example, by making the area of the upper surface 50a of the light-transmissive member 50 smaller than the area of the lower surface 50b, the area of the light-emitting surface is reduced, and a light-emitting device with a higher luminance can be obtained.

In a top view, the center of the lower surface 50b of the light-transmissive member 50 preferably overlaps the center of the lower surface 20b of the support substrate 20. In the present embodiment, the lower surface 20b of the support substrate 20 is a surface closer to the light-emitting layer than the upper surface thereof is. This allows the center of a light-emitting portion of the light-emitting element 23 and the center position of the lower surface 50b of the light-transmissive member 50 to be close to each other, thereby reducing unevenness of light incident on the light-transmissive member 50.

The light-transmissive member 50 may use, for example, an inorganic material such as glass, ceramic, or sapphire, or an organic material such as a resin or a hybrid resin containing one or more of a silicone resin, a modified silicone resin, an epoxy resin, a modified epoxy resin, an acrylic resin, a phenol resin, and a fluororesin. The light-transmissive member 50 may contain a wavelength conversion member, that is, a phosphor, that can convert the wavelength of at least a portion of incident light. Examples of the light-transmissive member 50 containing the phosphor include a sintered body of phosphor and a material in which phosphor powder is contained in the above-described material. The light-transmissive member 50 may be a member in which a light-transmissive layer such as a resin layer containing a phosphor or a glass layer containing a phosphor is disposed on a surface of a component formed of resin, glass, ceramic, or the like. The light-transmissive member 50 may contain a filler such as a diffusing member depending on the purpose. In the case in which the light-transmissive member 50 contains a filler such as a diffusing member, the light-transmissive member 50 may be formed of resin, glass, ceramic, or any other inorganic material containing a filler, or may include a light-transmissive layer such as a resin layer containing a filler or a glass layer containing a filler disposed on a surface of a light-transmissive plate that is a component formed of resin, glass, ceramic, or the like.

As the phosphor, an yttrium aluminum garnet-based phosphor (for example, (Y, Gd)₃(Al, Ga)₅O₁₂:Ce), a lutetium aluminum garnet-based phosphor (for example, Lu₃(Al, Ga)₅O₁₂:Ce), a terbium aluminum garnet-based phosphor (for example, Tb₃(Al, Ga)₅O₁₂:Ce), a CCA-based phosphor (for example, Ca₁₀(PO₄)₆Cl₂:Eu), an SAE-based phosphor (for example, Sr₄Al₁₄O₂₅:Eu) , a chlorosilicate-based phosphor (for example, Ca₈MgSi₄O₁₆Cl₂:Eu), a silicate-based phosphor (for example, (Ba, Sr, Ca, Mg)₂SiO₄:Eu), an oxynitride-based phosphor such as a β-SiAlON-based phosphor (for example, (Si, Al)₃(O, N)₄:Eu) or an α-SiAlON-based phosphor ( for example, Ca(Si, Al)₁₂(O, N)₁₆:Eu), a nitride-based phosphor such as an LSN-based phosphor (for example, (La, Y)₃Si₆N₁₁:Ce), a BSESN-based phosphor (for example, (Ba, Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr, Ca)AlSiN₃:Eu), a fluoride-based phosphor such as a KSF-based phosphor (for example, K₂SiF₆:Mn) , a KSAF-based phosphor (for example, K₂(Si₁₋ₓAlₓ) F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs, FA, MA) (Pb, Sn) (F, Cl, Br, I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag, Cu) (In, Ga) (S, Se)₂), or the like can be used.

As the light diffusion member, those known in the art can be used. For example, titanium oxide, silicon oxide, aluminum oxide, or barium titanate can be used.

When a resin is used as a base material of the light-transmissive layer, examples of the resin include thermosetting resins such as an epoxy resin, a modified epoxy resin, a silicone resin, and a modified silicone resin.

An optical film may be disposed on the upper surface and/or the lower surface of the light-transmissive member 50. Examples of the optical film include the same films as those disposed on the light-emitting element.

### Covering Member 60

The covering member 60 preferably allows the upper surface 50a of the light-transmissive member 50 to be exposed and covers the protective element 30. The covering member 60 preferably has a light-blocking property, and specifically has a light-reflecting property and/or a light-absorbing property. In particular, a material that can suitably reflect light emitted from the light-emitting element 23 is preferably contained in the covering member 60. For example, the material preferably has a reflectance of 60% or more, 70% or more, 80% or more, or 90% or more with respect to the light emitted from the light-emitting element 23.

The covering member 60 preferably covers all of the lateral surfaces of the adhesive member 40 and all of the lateral surfaces of the light-transmissive member 50. The covering member 60 may cover the lateral surfaces of the light-emitting element 23 exposed from the adhesive member 40 and the lower surface 20b of the light-emitting element 23, or may cover the upper surface of the substrate 10. The covering member 60 can constitute an outer surface of the light-emitting device 1.

With the covering member 60 covering the lateral surfaces of the adhesive member 40, light emitted from the lateral surfaces of the light-emitting element 23 and transmitted through the adhesive member 40 is reflected by the covering member 60. Furthermore, because the covering member 60 covers the lower surface of the light-emitting element 23, light emitted from the lower surface of the light-emitting element 23 and traveling downward is reflected by the covering member 60. Thus, light extraction efficiency in the light-emitting device 1 can be improved.

Preferably, the covering member 60 is formed using an insulating material. The covering member 60 is, for example, a member in which particles of a light-reflective substance are contained in a light-transmissive resin. Examples of the resin to be used for the covering member 60 include a resin or a hybrid resin containing one or more of a silicone resin, a modified silicone resin, an epoxy resin, a modified epoxy resin, a urea resin, an acrylic resin, a phenol resin, a bismaleimide triazine resin, and a polyphthalamide resin. Among these, it is particularly preferable to use a silicone resin which is good in light resistance, heat resistance, and electrical insulation properties and has flexibility. Examples of the light-reflective substance include titanium oxide, silicon oxide, aluminum oxide, zirconium oxide, magnesium oxide, potassium titanate, barium titanate, zinc oxide, silicon nitride, aluminum nitride, boron nitride, calcium carbonate, calcium hydroxide, calcium silicate, and combinations thereof. Among these, from the perspective of light reflection, titanium oxide, which has a relatively high refractive index, is preferably employed.

The covering member 60 may be made up of a single covering member or a plurality of covering members. As illustrated in FIG. 1E, the covering member 60 may be made up of a first covering member 61 and a second covering member 62. The first covering member 61 is provided on the substrate 10, for example, and covers the lower surface of the light-emitting element 23 and at least part of the lateral surfaces of the adhesive member 40. The first covering member 61 preferably covers the lower surface and at least part of the lateral surfaces of the protective element 30.

The second covering member 62 is provided on the first covering member 61, for example, and covers the lateral surfaces of the light-transmissive member 50. The second covering member 62 covers the upper surface of the protective element 30. The second covering member 62 may cover part of the lateral surfaces of the light-transmissive member 50 and part of the lateral surfaces of the protective element 30. The lateral surfaces of the second covering member 62 constitute the lateral surfaces, that is, the outer surfaces, of the light-emitting device 1, together with the lateral surfaces of the base body 11 of the substrate 10. The lateral surfaces of the second covering member 62 and the lateral surfaces of the base body 11 may be flush with each other, for example. The upper surface of the second covering member 62 and the upper surface 50a of the light-transmissive member 50 can be flush with each other, for example.

The covering member 60 is made up of the first covering member 61 and the second covering member 62, so that for example, the second covering member 62 constituting the outer surfaces of the light-emitting device 1 can be formed of a material having a high mechanical strength, while the first covering member 61 covering the lower surface of the light-emitting element 23 can be formed of a material having a low elastic modulus and a low linear expansion coefficient, to make it possible to relax a stress due to a difference in expansion coefficient.

### Operation of Light-Emitting Device 1

In the light-emitting device 1, when a current is supplied from an external power supply to the light-emitting element 23, the light-emitting element 23 emits light. Of the light emitted from the light-emitting element 23, the light traveling upward (that is, toward the lower surface of the light-transmissive member) is extracted to the outside of the light-emitting device 1 through the adhesive member 40 and the light-transmissive member 50. Of the light emitted from the light-emitting element 23, the light traveling downward is reflected by the covering member 60 and the substrate 10, and extracted to the outside of the light-emitting device 1 through the adhesive member 40 and the light-transmissive member 50.

Of the light emitted from the light-emitting element 23, light traveling in the lateral direction is reflected at an interface between the lateral surface of the adhesive member 40 and the covering member 60 and extracted to the outside of the light-emitting device 1 through the adhesive member 40 and the light-transmissive member 50. In this case, because the lateral surface 40c of the adhesive member 40 has an outer surface including a concave curved surface, the amount of the adhesive member 40 covering the lateral surfaces of the light-emitting element 23 can be increased without allowing the adhesive member to be in contact with the protective element. Further, the adhesive member 40 covering the lateral surfaces of the light-emitting element 23 is less likely to contact with the protective element 30. The light propagating from the light-emitting element 23 to the protective element 30 side is less likely to be absorbed by the protective element 30. As a result, the efficiency of light extraction from the light-emitting element 23 can be further improved.

Furthermore, because the lateral surface 40d of the adhesive member 40 has an outer surface including a convex curved surface, the amount of the adhesive member covering the lateral surfaces of the light-emitting element 23 can be further increased. This allows the surface area of an interface between the lateral surface 40d of the adhesive member, which serves as a reflective surface, and the covering member 60 to increase, and allows light to be reflected more efficiently. This allows the light-emitting device 1 to have even better light extraction efficiency.

### Second Embodiment

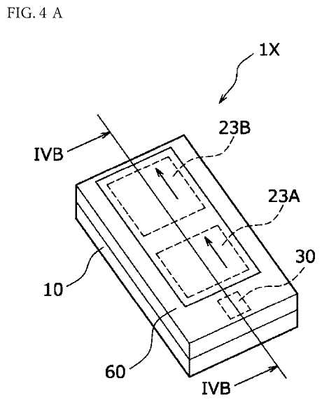

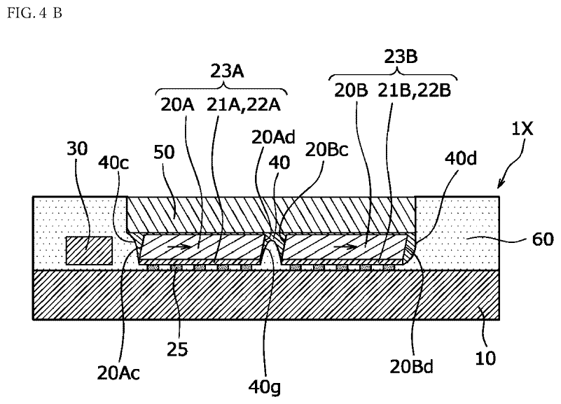

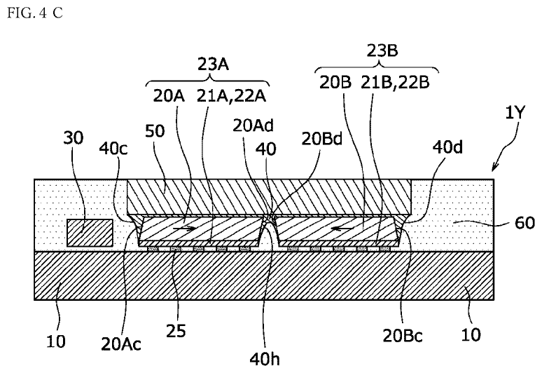

As illustrated in FIGS. 4A and 4B, in a light-emitting device 1X according to the present embodiment, two light-emitting elements 23A and 23B and a protective element 30 are disposed in a line on the substrate 10. As illustrated in FIG. 4B, the cross-sectional shapes of supporting substrates 20A and 20B in the two light-emitting elements 23A and 23B are, respectively, parallelograms. Arrows illustrated in FIGS. 4A and 4B each indicate a direction in which facing lateral surfaces of the parallelograms are inclined from the lower end toward the upper end.

Here, in the light-emitting element 23A facing the protective element 30, an upper end of a first lateral surface 20Ac of the support substrate 20A is located at a greater distance from the protective element 30 than a lower end of the first lateral surface 20Ac is. A second lateral surface 20Ad of the support substrate 20A is substantially parallel to the first lateral surface 20Ac. A third lateral surface and a fourth lateral surface of the support substrate 20A are substantially perpendicular to a lower surface of the support substrate 20A.

In the light-emitting element 23B facing the light-emitting element 23A, a first lateral surface 20Bc and a second lateral surface 20Bd of the support substrate 20B are substantially parallel to the first lateral surface 20Ac and the second lateral surface 20Ad of the support substrate 20A of the light-emitting element 23A. That is, the second lateral surface 20Ad of the support substrate 20A of the light-emitting element 23A and the first lateral surface 20Bc of the support substrate 20B of the light-emitting element 23B face each other.

The light-transmissive member 50 has a quadrilateral shape in a top view, and the lateral surfaces thereof are substantially perpendicular to the upper surface and the lower surface. One light-transmissive member 50 is disposed on the two light-emitting elements 23A and 23B, and encloses the upper surfaces of the two light-emitting elements 23A and 23B in a top view.

The adhesive member 40 bonds the upper surfaces of the two light-emitting elements 23A and 23B (that is, the upper surfaces of the two support substrates 20A and 20B) and the lower surface of the light-transmissive member 50 to each other. The lateral surface 40c of the adhesive member 40 covering the first lateral surface 20Ac of the support substrate 20A has an outer surface including a concave curved surface. The lateral surface 40d of the adhesive member 40 covering the second lateral surface 20Bd of the support substrate 20B has an outer surface including a convex curved surface. A lateral surface 40g of the adhesive member 40 between the support substrate 20A and the support substrate 20B is continuous from the second lateral surface 20Ad of the support substrate 20A to the first lateral surface 20Bc of the support substrate 20B, and defines a concave portion having an outer surface including a concave curved surface. The adhesive member 40 located at the second lateral surface 20Ad side is thinner than the first lateral surface 20Bc side. Other configurations of the light-emitting device are substantially the same as or similar to those of the light-emitting device 1.

### First Modified Example

In the light-emitting device 1X described above, as a light-emitting device 1Y, the support substrate 20A of the light-emitting element 23A may be configured such that the upper end of the first lateral surface 20Ac is located at a greater distance from the protective element 30 than the lower end thereof is, as in the light-emitting device 1X, and the support substrate 20B of the light-emitting element 23B may have such a configuration in which the first lateral surface 20Ac and the second lateral surface 20Ad of the support substrate 20A of the light-emitting element 23A are reversed. That is, in the light-emitting device 1Y, the second lateral surface 20Ad of the support substrate 20A of the light-emitting element 23A and the second lateral surface 20Bd of the support substrate 20B of the light-emitting element 23B may be disposed so as to face each other. Specifically, as illustrated in FIG. 4C, the cross-sectional shapes of the support substrates 20A and 20B in the two light-emitting elements 23A and 23B, respectively, are parallelograms, and the facing lateral surfaces are inclined so as to become closer to each other from the lower end toward the upper end. Arrows illustrated in FIG. 4C indicate the directions in which the facing lateral surfaces of the parallelograms are inclined from the lower end toward the upper end. In this case, the lateral surfaces of the adhesive member 40 covering the first lateral surface 20Ac of the support substrate 20A and the lateral surfaces of the adhesive member 40 covering the first lateral surface 20Bc of the support substrate 20B may each have an outer surface including a concave curved surface. A lateral surface 40h of the adhesive member 40 between the support substrate 20A and the support substrate 20B is continuous from the second lateral surface 20Ad of the support substrate 20A to the second lateral surface 20Bd of the support substrate 20B, and defines a concave portion having an outer surface including a concave curved surface. The thickness of the concave portion (that is, the thickness of the thinnest portion of the adhesive member 40 covering the lower surface of the light-transmissive member 50 between the light-emitting element 23A and the light-emitting element 23B) is larger than the thickness of the concave potion between the light-emitting element 23A and the light-emitting element 23B in the light-emitting device 1X described above. This can reduce luminance unevenness of light emitted from a light-emitting surface of the light-emitting device 1Y (that is, the upper surface of the light-transmissive member 50) when the light-emitting element 23A and the light-emitting element 23B emit light at the same time. Other configurations of the light-emitting device are substantially the same as or similar to those of the light-emitting device 1X.

With such configurations of the light-emitting devices 1X and 1Y, the amount of the adhesive member covering the lateral surfaces of the light-emitting element can be increased without allowing the adhesive member to be in contact with the protective element. This can improve the efficiency of light extraction from the lateral surfaces of the light-emitting element, and the adhesive member covering the lateral surfaces of the light-emitting element is less likely to be in contact with the protective element can be reduced. Also, the light emitted from the light-emitting element toward the protective element side is less likely to be absorbed by the protective element. As a result, the light extraction efficiency of the light-emitting element can be further improved.

### Third Embodiment

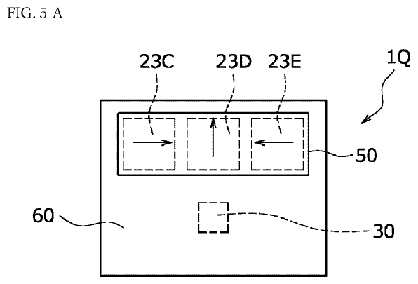

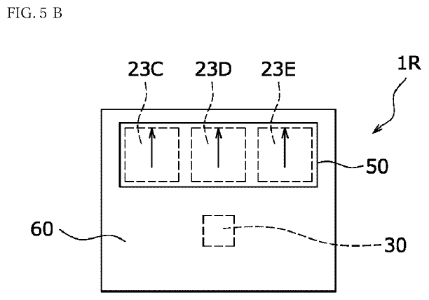

As illustrated in FIG. 5A, in a light-emitting device 1Q according to the present embodiment, three light-emitting elements 23C, 23D, and 23E are disposed in a line along one side of the substrate 10, and the protective element 30 is disposed on the other side of the substrate 10 so as to face the light-emitting element 23D in the center. The three light-emitting elements 23C, 23D, 23E each include a support substrate that has an upper surface and a lower surface each having a substantially quadrilateral shape, and has a first lateral surface and a second lateral surface each inclined in the same direction with respect to the lower surface. Arrows illustrated in FIG. 5A each indicate a direction in which a first lateral surface and a second lateral surface of the support substrate are inclined from the lower end toward the upper end.

Here, an upper end of the first lateral surface of the support substrate of the light-emitting element 23D facing the protective element 30 is located at a greater distance from the protective element 30 than a lower end of the first lateral surface is.

Thus, as described above, the amount 41 the adhesive member covering the lateral surfaces of the light-emitting element can be increased without allowing the adhesive member to be in contact with the protective element. This can improve the light extraction efficiency of the lateral surfaces of the light-emitting element, and the adhesive member covering the lateral surfaces of the light-emitting element is less likely to be in contact with the protective element. Also, the light emitted from the light-emitting element to the protective element side is less likely to be absorbed by the protective element can be reduced. As a result, the light extraction efficiency of the light-emitting element can be further improved.

Furthermore, the light-emitting elements 23C and 23E are each configured such that the lower end of the lateral surface of the support substrate facing the light-emitting element 23D is located at a greater distance from the light-emitting element 23D than the upper end of the lateral surface thereof is. Thus, the adhesive member 40 between the light-emitting elements 23C and 23D is continuous and is thicker than the adhesive member on the lateral surface of the light-emitting element 23C not facing the light-emitting element 23D. The adhesive member 40 between the light-emitting elements 23D and 23E is continuous and is thicker than the adhesive member on the lateral surface of the light-emitting element 23E not facing the light-emitting element 23D. Other configurations of the light-emitting device are substantially the same as or similar to those of the light-emitting device 1.

### Second Modified Example

In the light-emitting device 1Q described above, as a light-emitting device 1R, the light-emitting elements 23C and 23E are configured such that the upper ends of the first lateral surfaces 20c of the support substrates of the light-emitting elements 23C and 23E are located at a greater distance from the protective element 30 than the lower ends thereof are, similarly to the light-emitting element 23D. Arrows illustrated in FIG. 5B each indicates a direction in which the first lateral surface and the second lateral surface of the support substrate in each of the light-emitting elements are inclined from the lower end toward the upper end. Other configurations of the light-emitting device are substantially the same as or similar to those of the light-emitting device 1Q.

With such configurations of the light-emitting devices 1Q and 1R, the light extraction efficiency of the light-emitting element can be further improved substantially as in the light-emitting devices 1, 1X, and 1Y.

### Fourth Embodiment

As illustrated in FIG. 6A, a light-emitting device 1S according to the present embodiment is configured such that, four light-emitting elements 23F, 23G, 23H, and 23I are disposed in a line along one side of the substrate 10, and the protective element 30 is disposed on the other side of the substrate 10 so as to face two light-emitting elements 23G and 23H in the center.

Here, upper ends of first lateral surfaces of the light-emitting elements 23G and 23H each facing the protective element 30 are located at a greater distance from the protective element 30 than lower ends of the first lateral surfaces thereof are. Other configurations of the light-emitting device are substantially the same as or similar to those of the light-emitting device 1Q.

Thus, as described above, the amount of the adhesive member covering the lateral surfaces of the light-emitting element can be increased without allowing the adhesive member to be in contact with the protective element. This can improve the light extraction efficiency of the lateral surfaces of the light-emitting element. Furthermore, the adhesive member covering the lateral surface of the light-emitting element is less likely to become closer to the protective element side, and the light emitted from the light-emitting element toward the protective element side is less likely to be absorbed by the protective element. As a result, the light extraction efficiency of the light-emitting element can be further improved.

### Third Modified Example

As illustrated in FIG. 6B, in the light-emitting device 1S described above, as a light-emitting device 1U, the light-emitting elements 23F and 23I are configured such that the upper ends of the first lateral surfaces of the support substrates in the light-emitting elements 23F and 23I are located at a greater distance from the protective element 30 than the lower ends thereof are, similarly to the light-emitting elements 23G and 23H. Other configurations of the light-emitting device are substantially the same as or similar to those of the light-emitting device 1S.

With such configurations of the light-emitting devices 1S and 1U, the light extraction efficiency of the light-emitting element can be further improved substantially as in the light-emitting devices 1, 1X, 1Y, 1Q, and 1R.

What is claimed is:

1. A light-emitting device comprising:
a substrate;
a light-emitting element including,
a support substrate having an upper surface, a lower surface on an opposite side to the upper surface, and a first lateral surface between the upper surface and the lower surface, and
a semiconductor structure disposed on the lower surface of the support substrate,
the light-emitting element being disposed such that a surface on a lower surface side of the light-emitting element faces an upper surface of the substrate;
a protective element disposed on the substrate such that the protective element faces the first lateral surface;
a light-transmissive member disposed on an upper surface of the light-emitting element; and
an adhesive member bonding the upper surface of the support substrate and a lower surface of the light-transmissive member to each other while covering the first lateral surface, wherein
an upper end of the first lateral surface is located at a greater distance from the protective element than a lower end of the first lateral surface is.

2. The light-emitting device according to claim 1, wherein
the support substrate has a second lateral surface located on an opposite side to the first lateral surface, and
an upper end of the second lateral surface is located at a greater distance from the protective element than a lower end of the second lateral surface is.

3. The light-emitting device according to claim 1, wherein
the first lateral surface is inclined with respect to the lower surface of the support substrate.

4. The light-emitting device according to claim 2, wherein
the first lateral surface and the second lateral surface are inclined with respect to the lower surface of the support substrate.

5. The light-emitting device according to claim 4, wherein
the support substrate has a third lateral surface and a fourth lateral surface, each of the third lateral surface and the fourth lateral surface being adjacent to the first lateral surface and the second lateral surface, and
the third lateral surface and the fourth lateral surface are perpendicular to the lower surface of the support substrate.

6. The light-emitting device according to claim 5, wherein
the lower surface of the light-transmissive member encloses the upper surface and the lower surface of the support substrate in a top view.

7. The light-emitting device according to claim 6, wherein
the adhesive member covers the second lateral surface.

8. The light-emitting device according to claim 7, wherein
a portion of the adhesive member covering the second lateral surface has an outer surface including a convex curved surface.

9. The light-emitting device according to claim 8, wherein
a portion of the adhesive member covering the first lateral surface has an outer surface including a concave curved surface.

10. The light-emitting device according to claim 7, wherein
a lower end of a portion of the adhesive member on a side of the second lateral surface of the support substrate is closer to the substrate than a lower end of a portion of the adhesive member on a side of the first lateral surface of the support substrate is.

11. The light-emitting device according to claim 1, wherein
a center of the lower surface of the light-transmissive member overlaps a center of the lower surface of the support substrate in a top view.

12. The light-emitting device according to claim 1, wherein
an upper surface of the light-transmissive member has an area smaller than an area of the lower surface of the light-transmissive member.

13. The light-emitting device according to claim 12, wherein
the light-transmissive member includes a first portion in which the upper surface and the lower surface of the light-transmissive member overlap each other in a top view, and a second portion located on outward of the first portion, and
the second portion of the light-transmissive member overlaps the first lateral surface of the support substrate in the top view.

14. The light-emitting device according to claim 1, wherein
the light-transmissive member includes a wavelength conversion member.

15. The light-emitting device according to claim 1, wherein
the adhesive member is spaced apart from the protective element and the substrate.

16. The light-emitting device according to claim 1, further comprising:
a covering member covering the protective element with an upper surface of the light-transmissive member being exposed from the covering member.
